(19) United States
(12) Patent Application Publication
(10) Pub. No.: US 2026/0133338 A1
(43) Pub. Date: May 14, 2026

(54) MAGNETIC DETECTION DEVICE AND METHOD

(71) Applicant: FNV IP B.V., Leidschendam (NL)

(72) Inventors: Peter NIEUWVELD, Leidschendam (NL); Rik WEMMENHOVE, Leidschendam (NL); Ahmed Abdelaziz Mohamed ALDIH, Leidschendam (NL)

(73) Assignee: FNV IP B.V., Leidschendam (NL)

(21) Appl. No.: 19/118,720

(22) PCT Filed: Aug. 18, 2023
(86) PCT No.: PCT/EP2023/072796

§ 371 Date: Apr. 4, 2025

(30) Foreign Application Priority Data
Oct. 18, 2022 (NL) 2033345

(51) Int. Cl. G01V 3/15; G01R 33/26; G01V 3/08

(52) U.S. Cl. CPC G01V 3/15; G01R 33/26; G01V 3/081

(57) ABSTRACT

The invention relates to a magnetic detection device for measuring magnetic properties below the surface of the ground, the magnetic detection device comprising at least one sensor housing, the sensor housing defining a housing space and at least one optically pumped magnetometer provided in the housing space of the sensor housing, wherein the optically pumped magnetometer is a vector magnetometer arranged to provide information on a magnetic field in three substantially orthogonal directions. The invention further relates to a method for detecting subsurface bodies, a system for deploying a magnetic detection device, a computer readable medium, and a kit of parts for a magnetic detection device. Unlocking insights from Geo-Data, the present invention further relates to improvements in sustainability and environmental developments: together we create a safe and liveable world.

### FIELD OF THE INVENTION

The present disclosure generally relates to a magnetic detection device for measuring magnetic properties below the surface of the ground. The invention further relates to a method for detecting subsurface bodies, a system for deploying a magnetic detection device, a computer readable medium, and a kit of parts for a magnetic detection device.

### BACKGROUND OF THE INVENTION

There is a general and ongoing need to improve the quality and efficiency of data acquisition of characteristics of the ground. Such data acquisition is referred to as subsurface information acquisition, subsurface being understood as any region under the surface of the ground. Subsurface information may be used for e.g., site characterisation for infrastructure projects, foundation calculations, pipeline inspection, unexploded ordinances (UXO) detection, and the like. For all of these applications, it is important to generate a comprehensive subsurface image with a high degree of accuracy in an efficient manner.

Advantageously, such magnetic detection is done in an non-intrusive manner. This mitigates the need for physical subsurface testing, which is expensive, has an inherent risk, and takes a large amount of time. Previous attempts to address this have included the use of standard marine magnetometers, which are total field magnetometers measuring the total ambient magnetic field. These magnetometers are known to be large, heavy, and power inefficient. Using such magnetometers results in measurements being performed in an inefficient manner since the use of these magnetometers in the water leads to high energy expenditure. Furthermore, due to their size, the total number of magnetometers that can be simultaneously deployed is limited. As a result, the resolution of acquired data is low and the resulting ground models can be inaccurate.

A type of total field magnetometer that is used is the atomic magnetometer. These are generally used since they are sensitive enough to achieve the objectives of a typical marine geophysical survey—and particularly a marine UXO survey. In the scenario where the survey instruments—including the magnetometers-are towed over the seabed behind a survey vessel, it is unsafe to tow the survey instruments too close to the seabed.

If the survey instruments are towed too close to the seabed, they are at risk of impacting the seabed, which results in high costs and safety issues. The minimum safe deployment altitude above the seabed, plus the deepest expected burial depth of the objects of interest dictates the range of detection that is required of the magnetometers and other survey sensors. Atomic total field magnetometers are the only magnetometers currently used to achieve the sensitivities and thus range of detection required for typical marine UXO survey requirements.

While these atomic magnetometers are generally sufficiently sensitive to perform UXO surveys, they are large, heavy, and power inefficient, leading to a lack of operational efficiency and limited data resolution.

Furthermore, such known magnetometers only measure the total magnetic field, and thus do not provide accurate information on the direction of the magnetic field, which introduces uncertainties in the acquired data.

When the large total field atomic magnetometers are used, a balance is required between deploying a large enough array of sensors to be efficient, and the limits of practically and safely deploying said array. Since the total field atomic magnetometers are so large and heavy, they pose deployment risks with respect to the launch and recovery risks to equipment and personnel, as well as risks associated with the navigation of a large and heavy array of magnetometers with respect to the seabed and associated obstacles such as rocks, sand dunes, and the like.

Other known magnetometers, such as e.g., fluxgate magnetometers, provide higher data resolution and measure vector fields as well as total fields. However, these magnetometers lack sensitivity and cannot be used in most marine geophysical surveys. They must be deployed much closer to the seabed and often travel much slower, resulting in increased operation times and reduced efficiency.

There is thus a need for an improved magnetic detection device that addresses at least one of the problems described above.

### BRIEF SUMMARY OF THE INVENTION

In one aspect of the invention there is provided a magnetic detection device for measuring magnetic properties below the surface of the ground. The magnetic detection device comprises at least one sensor housing. The sensor housing defining a housing space and at least one optically pumped magnetometer provided in the housing space of the sensor housing, wherein the optically pumped magnetometer is a vector magnetometer arranged to provide information on a magnetic field in three substantially orthogonal directions.

The magnetic detection device may be moved over the seabed such that the optically pumped magnetometer measures the magnetic field in three substantially orthogonal directions simultaneously. By moving the magnetometer, three-dimensional data is acquired along different locations where the magnetic detection device is moved. Notably, by using an optically pumped vector magnetometer, each measurement is taken at a single point, and simultaneously. This is generally done by shining lasers through a single vapour cell from three sides and analysing the transmission to determine the magnetic field strength relative to the direction of the laser.

This approach of measuring the magnetic field in three directions has the advantage that spatial and/or time-related errors are mitigated. The measurements are taken at a single position, and at a single time. Having three separated measurements by e.g., using a single-direction magnetometer and turning the magnetometer 90 degrees after each measurement introduces a time-uncertainty due to the required time for adjusting the orientation of the magnetometer and a spatial uncertainty since the magnetometer is moved.

The use of an optically pumped vector magnetometer is advantageous as it is able to provide information on a magnetic field in three substantially orthogonal directions at a single point in time and space. As a result, the information obtained from a single magnetometer is increased. Furthermore, the application of an optically pumped magnetometer, rather than the traditional total field magnetometers, leads to a significant reduction in weight of the overall system.

In addition, the use of an optically pumped vector magnetometer also greatly reduces the overall size, weight, and power requirement of the measurement system. As a result, the overall drag on the system when submerged in the water is reduced. More sensors can be deployed as a result of this, or a limited number of sensors can be deployed with less energy required. This may lead to longer measurement time, or increased coverage area. As a result, a larger region of the ground can be analysed.

Alternatively, or additionally, the resolution of the measurement may be increased, if a larger number of sensors is arranged on a similar spatial arrangement, having a similar velocity through the water. Finally, while known systems require large amounts of power to be supplied to the sensor, leading to lower efficiency, the use of an optically pumped vector magnetometer limits the energy expenditure and allows for the deployment of a greater number of magnetometers on a given power supply.

In an advantageous embodiment, the housing space is waterproof. Waterproof in the context of this disclosure means protected against a general ingress of water at atmospheric pressure.

In an embodiment, the sensor housing comprises a non-magnetic material. In an embodiment, the sensor housing comprises a non-conductive material. In a preferred embodiment, the sensor housing comprises a non-conductive and non-magnetic material. In an embodiment, the sensor housing comprises one or more of a non-magnetic stainless steel or brass. In an embodiment, the sensor housing comprises a non-metallic material.

In an embodiment, the sensor housing comprises at least one of Glass-Reinforced Plastic (GRP), also known as fibreglass, high-density polyethylene (HDPE), polyamides such as homopolymers and copolymers of PA46, PA48, PA410, PA46/6T, PA4T, PA6, PA610, PA6T, PA6/6T, PA6/10T, PA910, PA9T, polyesters, nylon, carbon fibre, plastics, polymers, advantageously ultra-high molecular weight polymers (such as ultra-high molecular weight polyethylene), ultra-high density polymers (such as ultra-high density polyethylene), polyoxymethylene, resins, polyamides, polyether ether ketones, or polycarbonates. In the context of the present invention, the term ‘polymer’ is to be understood as a homopolymer or a copolymer. In an embodiment, the sensor housing comprises at least about 50%, advantageously at least about 70%, more advantageously at least about 90% of non-magnetic, advantageously non-conductive, more advantageously non-metal materials.

Optically pumped magnetometers (OPMs) are, in principle, scalar-type quantum sensors for magnetic fields based on the Zeeman effect. That is the shift of energy levels due to the interaction of atoms with an external magnetic field. Usually alkali vapours in paraffin-coated glass cells are used as sensing element. Other embodiments may also be used as appropriate. Because the energy shift by the Zeeman interaction is based on the scalar product of the measured external magnetic field B^{→}O and the magnetic moment of the atom, such a magnetometer measures the absolute value of the field.

In an embodiment, the optically pumped vector magnetometer is a total-field optically pumped magnetometer (total-field OPM). Total-field OPMs can operate in Earth's field with high accuracy. The atoms in the OPM vapor cell advantageously have a well-defined precession frequency that is directly proportional to the magnitude of the background field. In an embodiment, the precession frequency is directly measured with a high-resolution frequency counter to obtain the value of background magnetic field. In an embodiment, the total-field OPM is well suited for applications in Earth's field that require very high accuracy. In an embodiment, the optically pumped vector magnetometer is a pulsed, rubidium optically pumped magnetometer (OPM). In an embodiment, the optically pumped vector magnetometer is based on an optical detection scheme called Free Induction Decay (FID).

In an embodiment, the magnetometer comprises a laser, a transparent vapour cell defining a space therein, and a photodiode, wherein the transparent vapour cell is positioned between the laser and the photodiode. In a preferred embodiment, the laser is a 795 nm VCSEL laser. Advantageously, the light is circularly polarized using a quarter waveplate, positioned between the laser and the vapour cell. In a preferred embodiment, the vapour cell comprises a Rubidium vapour. The circularly polarized light passes through the transparent rubidium vapour cell. After passing through the vapour cell, the light is captured by the photodiode. Advantageously, the vapour cell is electrically heated to between about 70 and 90° C., advantageously to about 80° C. This increases rubidium vapor pressure. The laser wavelength is advantageously electronically locked to the rubidium optical transition.

In a preferred embodiment, the sensor operation is divided into two phases that repeat at given time intervals, advantageously about every 1 millisecond. In such an embodiment, for the first 500 μs, a strong polarizing magnetic field (Bp) parallel to the light beam is turned on using a set of Helmholtz coils enveloping the vapor cell. The combination of the light beam and the longitudinal polarizing field causes the rubidium atoms to become spin-polarized (aligned with the polarization field). Next, the polarizing field is rapidly turned off in less than 1 μs. Once the polarization field is turned off, the measurement phase begins.

Rapidly switching off of the polarization field causes precession (oscillation) in the rubidium atoms about the earth's magnetic field. The rubidium precession frequency is directly proportional to the background magnetic field. The precession of rubidium atoms modulates the light passing through the vapor cell which enables real-time observation of this precession, for example using the amplified photodiode output plugged into an oscilloscope. Advantageously, the precession lasts for about 500 μs and constitutes the measurement phase of the cycle.

In an embodiment, during the measurement phase, the raw electrical output from the photodiode is amplified and sent to a built-in high-performance frequency counter. The frequency counter measures the rubidium precession frequency and infers the accurate value of the background magnetic field, thanks to the fixed relationship between background magnetic field and precession frequency.

As an example, the optically pumped vector magnetometer can be a magnetometer as defined in U.S. Pat. No. 10,088,535, which is incorporated herein by reference. As an example, the optically pumped vector magnetometer can be a magnetometer as defined in US20180238974, which is incorporated herein by reference. As an example, the optically pumped vector magnetometer can be a magnetometer as defined in U.S. Pat. No. 10,775,450, which is incorporated herein by reference.

In an embodiment, the optically pumped vector magnetometer comprises two alkali vapor cells, or sets of alkali atoms contained in some manner, separated by a distance referred to as the baseline of the magnetometer. Instead of passing the pump/probe beam through just one contained locations or cells of atoms, it passes through two or both contained locations or cells consecutively. After both spin-ensembles have been pumped simultaneously, the holding field is suddenly switched off and the spins in both cells precess at their respective Larmor frequencies ωL1=γB1 and ωL2=γB2, where B1 and B2 represent the magnetic fields at the locations of the two cells, respectively. The two vapor cells modulate the probe beam at both frequencies, and a beat can be seen on the photodiode at the difference frequency Δω=γ·|B1−B2|=γ·∇B·Δ, where Δ is the baseline. The beat frequency is therefore directly proportional to the magnetic field gradient ∇B and can be extracted independently even without the knowledge of independent magnetometer outputs. The advantage of this method is that the beat note frequency depends only on the gradient field and is therefore immune to parameter drifts such as probe laser frequency or amplitude.

In a preferred embodiment, the magnetic detection device further comprises at least one tow line, the tow line being directly or indirectly attached to the sensor housing. In a preferred embodiment, the at least one tow line is arranged to supply power to the at least one optically pumped magnetometer. In an additional or alternative embodiment, the at least one tow line is arranged to transmit measurement data.

The tow line is advantageously arranged to supply power so that the optically pumped magnetometer and/or other sensors in the magnetic detection device are powered. In an embodiment, the tow line is passive and is used solely to tow the magnetic detection device. In such an embodiment, a separate data and/or power cable may be provided such that the tow line provides the tensile force required to move the magnetic detection device through the water and a separate cable provides the data and/or power transmission.

In an embodiment, the magnetic detection device further comprises a power source, advantageously a battery, and a data storage unit. In such an embodiment, the data may be retrieved by the magnetometer and subsequently stored in the data storage unit. The power source may provide power to the magnetometer and the storage unit. Such an embodiment limits the necessity of data transmittance during operation and thus limits the requirements on e.g., a data transmission or power capability in the tow line. The tow line may also comprise solely a power supply or solely data transmission capabilities.

If a power unit is present, power transmission may be limited or made obsolete. Similarly, if a data storage unit is provided, data transmission may be limited or made obsolete. In an embodiment, the magnetic detection device further comprises a wireless data transmission unit, arranged to transmit at least a portion of the measurement date. In an embodiment, the tow line may be an interface cable, arranged to transmit the data generated from the at least one optically pumped magnetometer. In an embodiment, a plurality of tow lines is provided, each of these tow lines being attached to a sensor housing, such that several sensor housings, with optically pumped vector magnetometers being provided therein, are independently towed by the tow lines.

In an embodiment, the tow line is a power transmission cable, and the tow line comprises a power conversion unit. The power conversion unit is advantageously arranged to adapt the power supply so that it matches a power requirement of the optically pumped magnetometer.

The power conversion unit being provided in the tow line allows the sensor housing and the optically pumped magnetometer to be provided generically. The power conversion unit may also be provided in a power cable, which is separate from the tow line. If the sensor housing with the magnetometer is provided in a system having a different power output, changing the tow line with the power conversion unit is sufficient to allow normal operation of the magnetometer.

A different power conversion unit provided in another tow line can supply the appropriate power to the magnetometer. As such, the sensor housing and the magnetometer do not require adaptation if they are provided on different systems, leading to increased application flexibility.

In a preferred embodiment, one sensor housing has a weight of less than about 5 kg, advantageously of less than about 3 kg, more advantageously of less than about 2 kg, still more advantageously of less than about 1 kg. These weights can be achieved through the use of an optically pumped magnetometer since the optically pumped magnetometer is light. In an embodiment, the optically pumped magnetometer has a weight of between about 1 g and 0,5 kg, advantageously of between about 5 g and 200 g, more advantageously of between about 8 g and 100 g, still more advantageously of between about 10 g and 50 g, most advantageously of between about 12 g and 24 g. In a still more preferred embodiment, the optically pumped magnetometer has a weight of about 18 g.

The use of a sensor housing having a low weight, at least in part due to the low weight of the optically pumped magnetometer, increases deployment capabilities. The efficiency of the system is increased as the towed weight per magnetometer is reduced. The result of a lower weight is that the total number of sensors may be increased, thus increasing the coverage area of the magnetic detection device. These weights are measured in air at atmospheric pressure, and in earths average gravitational field.

In an embodiment, the at least one sensor housing defines a substantially cylindrical shape, having a length of less than about 1,5 m, advantageously of less than about 1 m, more advantageously of less than about 0,7 m, still more advantageously of less than about 0,5 m. In an additional or alternative embodiment, the at least one sensor housing has a diameter of less than about 40 cm, advantageously of less than about 20 cm, more advantageously of less than about 15 cm, still more advantageously of less than about 10 cm.

The reduced size and weight of the magnetic detection device allows for the deployment of more sensors, which may increase the resolution of the survey being carried out. Additionally, the use of a magnetic detection device having a reduced size and weight may allow for covering a larger area in a given amount of time. Having a sensor housing of a limited size allows for reduced drag in the water, allowing for a greater number of magnetometers to be deployed, thus increasing the coverage area of the survey.

In an embodiment, the magnetic detection device further comprises a frame. In an embodiment, the frame is arranged to support the at least one sensor housing. Advantageously, the frame is arranged to translate a towing force to the at least one sensor housing such that the at least one sensor housing can be moved through water.

When using multiple magnetometers, each provided in a sensor housing, the frame provides a rigid support for the magnetometers, such that they define a distance between each other that does not change. In a preferred embodiment, the magnetic detection comprises a frame and the magnetic detection device comprises a tow line, the tow line being attached to the frame. This is advantageous since it mitigates uncertainty with respect to the positions of the magnetometers. In an alternative embodiment, wherein the magnetic device comprises a frame, the tow line is still connected to the sensor housing, rather than the frame.

In an embodiment the frame comprises at least one of: steel, aluminium, carbon fibre, titanium, plastics. In a preferred embodiment, the frame comprises aluminium and High-Density Polyethylene (HDPE) plastic. In an advantageous embodiment, the material of the frame is non-magnetic, and advantageously also non-conductive. This increases the accuracy of the data acquisition of the magnetometer.

In an embodiment, the frame may comprise at least one fin, extending from the frame, the fin being arranged to stabilise the frame when the frame is towed through water. At least a section of the frame may be formed such that it acts as a hydrodynamic stabilizer such as e.g., a hydrofoil-shaped wing.

In an embodiment, the frame comprises at least one of Glass-Reinforced Plastic (GRP), also known as fibreglass, high-density polyethylene (HDPE), nylon, or similar plastics. In an embodiment, the frame comprises at least about 50%, advantageously at least about 70%, more advantageously at least about 90% of non-metal materials.

In an embodiment, the magnetic detection device further comprises a towing line. In an embodiment, the frame further comprises a connection unit, the connection unit connecting the frame with the towing line. The towing line may be a steel line, or a composite line. Known towing systems may be utilised to move the frame through the water. In an embodiment, the towing line is a tow line, the tow line being arranged to transmit data and/or power.

In an embodiment, the tow line may be an armoured coax data and/or power cable, arranged to transmit data and power, and to simultaneously provide a towing force to the frame. In an embodiment, the tow line comprises at least one optical fibre, arranged to transmit data. In embodiment, the magnetic detection device comprises a separate data transmission cable comprising at least one optical fibre.

In a preferred embodiment, the frame comprises a frame motion sensor, the frame motion sensor being attached to the frame and arranged to measure a directional and/or rotational velocity of the frame.

By providing the magnetometers to the frame, and providing a frame motion sensor to the frame, the motion of all magnetometers can be determined, with only a single frame motion sensor. This is because the relative distances between the magnetometers is defined by use of the frame. Alternatively, or additionally, in an embodiment, the at least one sensor housing comprises a sensor housing motion sensor, arranged to measure a directional velocity and/or rotational velocity of the sensor housing.

In a preferred embodiment, the sensor housing motion sensor is arranged to measure acceleration in three translational and three rotational axes. This is generally referred to as a six-dimensional measurement. In embodiments where the magnetometers are not provided on a rigid frame, the use of sensor housing motion sensors is particularly advantageous, since the directional velocity of the magnetometers can be measured, such that the measurement results of the magnetometers can be correlated with less uncertainty.

In a preferred embodiment, the magnetic detection device, further comprises a subsea tow body. Advantageously, the subsea tow body is directly or indirectly coupled to the sensor housing. In an embodiment, the subsea tow body comprises at least one hydrodynamic surface being arranged to determine a depth of the magnetic detection device.

The subsea tow body may be rigidly connected to the frame through at least one deployment frame arm. In an embodiment, the subsea tow body is pivotably connected to the frame. Alternatively, the subsea tow body is pivotably connected to the deployment frame arm. In a preferred embodiment, the magnetic detection device comprises a tow line, the tow line being attached to the subsea tow body.

In a preferred embodiment, the subsea tow body comprises a rotational axis, positioned substantially orthogonal to the direction of movement of the magnetic detection device, such that the subsea tow body is pivotably connected to the frame at the position of the rotational axis. In a preferred embodiment, the subsea tow body comprises at least one drive, advantageously an electronic drive, to change the position of the subsea tow body relative to the frame and/or the deployment frame arm such that the inclination of the subsea tow body is altered. This allows for steering the depth of the magnetic detection device.

In a preferred embodiment, the magnetic detection device comprises at least 2, advantageously at least 5, more advantageously at least 10 sensor housings, each having an optically pumped vector magnetometer in its housing space. Because the optically pumped vector magnetometers are more efficient, lighter, and smaller than the conventional systems, more magnetometers may be simultaneously deployed. This improves measurement resolution through data acquisition density, as well as the total covered area in a given amount of time.

Advantageously, the use of optically pumped vector magnetometers aids in the reduction of interference between magnets. In conventional systems, the atoms in the caesium vapour chamber are energized by an electric coil around the chamber. This coil causes its own electric field, which is relatively strong, which can influence other magnetometers if they are placed too close. Conventional magnetometers thus are not placed closer together than 1 m for this reason. The optically pumped vector magnetometers according to the present disclosure are advantageously energized by a laser, which does not cause a significant electromagnetic field. As a result, the sensors can be placed much closer together without a significant reduction in data quality as a result of interference. As a result, data acquisition resolution is increased.

In embodiments where the magnetic detection device comprises a frame, the sensor housings are advantageously attached to the frame, such that the frame translates a towing force to the sensor housings to move them through the water.

In an embodiment, the magnetic detection device comprises at least 50 sensor housings, advantageously at least 100 sensor housings, more advantageously at least 500 sensor housings, each having an optically pumped vector magnetometer in its housing space.

In a preferred embodiment, the magnetic detection device comprises at least 3 sensor housings, advantageously at least 10 sensor housings, the sensor housings being attached to the frame such that they define distances between one another that are substantially equal.

In an embodiment, the magnetic detection device comprises a plurality of sensor housings. Advantageously, each of the sensor housing has at least one optically pumped vector magnetometer in its housing space. Advantageously, at least two sensor housings are provided such that they define a vertical distance between them.

The use of multiple magnetometers which are provided in a horizontal line allows for the tracking of a gradient in the measurement results in a horizontal plane. The velocity of the magnetometers allows for data acquisitions at several points over an x-axis, which extends in the direction of movement of the magnetometer. As such, the change of the measurement results over time, along with the velocity of the magnetometer in relation to the seabed, provides an x-gradient of the measurements. The relative distance between the magnetometers, perpendicular to the direction of movement, allows for the determination of a y-gradient between the sensors. Finally, the provision of magnetometers over a vertical distance allows for the determination of a z-gradient in the measurement data, which is indicative of a change in magnetic characteristics in a vertical direction.

In an advantageous embodiment, the housing space is waterproof. Waterproof in the context of this disclosure means protected against a general ingress of water at atmospheric pressure.

In a preferred embodiment, the sensor housing has a depth rating of more than about 10 m, advantageously of more than about 50, more advantageously of more than about 100 m, still more advantageously of more than about 300 m.

The depth rating of the sensor housing provides the possibility of the magnetometers to be used at appropriate depths. As a result, they can be used in regions of high depths, without complex deployment systems. The depth rating is advantageously determined according to ISO 21173:2019. In an embodiment, the sensor housing has a ingress protection rating determined according to the IEC 60529 Ingress Protection (IP) code, advantageously wherein the sensor housing has an IP rating of IP68. IP68 refers to a dust-tight rating with respect to solid foreign objects and to a protection against the effects of continuous immersion in water. Any other applicable industry-standard determination of depth rating may also be applied to determine the appropriate depth rating of the sensor housing. In an embodiment, the sensor housing has a depth rating of more than about 1000 m, advantageously of more than about 3000 m, more advantageously of more than about 6000 m, still more advantageously of full ocean depth.

In a preferred embodiment, the sensor housing comprises a bulkhead connector. The bulkhead connector is advantageously arranged to transmit a signal from the housing space of the sensor housing. In an embodiment, the signal is transmitted to a tow line or to a data transmission cable and/or power cable, being connected to the sensor housing. In a preferred embodiment, the bulkhead has an inner connector, and an outer connector. The inner connector is advantageously connected to the magnetometer, and the outer connector is advantageously connected to the tow line.

According to an aspect of the present invention, there is provided a method for detecting subsurface bodies comprising the steps of: providing the magnetic detection device according to any of the embodiments disclosed herein; deploying the magnetic detection device in a body of water; moving the magnetic detection device through the body of water; and retrieving measurements results from the at least one optically pumped vector magnetometer.

Subsurface bodies relate to any object which is at least partially positioned under the surface of the ground. Subsurface in the context of this disclosure refers to everything under the surface of the ground, i.e., at any depth.

According to an aspect of the present invention, there is provided a system for deploying a magnetic detection device, comprising the magnetic detection device according to any of the embodiments disclosed herein; a vessel arranged to drag the magnetic detection device; a towing line, arranged to move the sensor housing, the towing line being connected to the vessel and the sensor housing of the magnetic detection device.

According to an aspect of the present invention, there is provided a computer readable medium having computer readable instruction stored thereon that, when executed by a processor of a magnetic detection device according to any of the embodiments herein, causes the magnetic detection device to measure characteristics of a magnetic field in three orthogonal directions.

According to an aspect of the present invention, there is provided a kit of parts for building the magnetic detection device according to any of the embodiments disclosed herein, comprising: at least one sensor housing, the sensor housing defining a housing space; at least one optically pumped magnetometer, arrange to be provided in the housing space of the sensor housing, wherein the optically pumped magnetometer is a vector magnetometer arranged to provide information on a magnetic field in three orthogonal directions.

### BRIEF DESCRIPTION OF THE DRAWINGS

In order to describe the manner in which the above-recited and other advantages and features of the disclosure can be obtained, a more particular description of the principles briefly described above will be rendered by reference to specific embodiments thereof which are illustrated in the appended drawings.

Understanding that these drawings depict only exemplary embodiments of the disclosure and are therefore not to be considered to be limiting of its scope, the principles herein are described and explained with additional specificity and detail through the use of the accompanying drawings in which:

FIG. 1 is a schematic view of the magnetic detection device according to an embodiment of the invention showing the magnetometer in the sensor housing;

FIG. 2 is a cross-sectional view of the magnetic detection device according to an embodiment of the invention showing the magnetometer in the sensor housing;

FIG. 3 is a side-view of the magnetic detection device according to an embodiment of the invention showing two sensor housings positioned on a frame being attached to a subsea tow body, which is attached to a tow line; and

FIG. 4 is a top view of the magnetic detection device according to an embodiment of the invention showing a plurality of sensor housings positioned on a frame, the frame being attached to a subsea tow body, which is attached to a tow line.

### DESCRIPTION OF ILLUSTRATIVE EMBODIMENTS

The following is a description of certain embodiments of the invention, given by way of example only and with reference to the drawings.

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting.

Numerous specific details are described to provide a thorough understanding of the disclosure. However, in certain instances, well-known or conventional details are not described in order to avoid obscuring the description. A reference to an embodiment in the present disclosure can be a reference to the same embodiment or any other embodiment. Such references thus relate to at least one of the embodiments herein.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods, and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

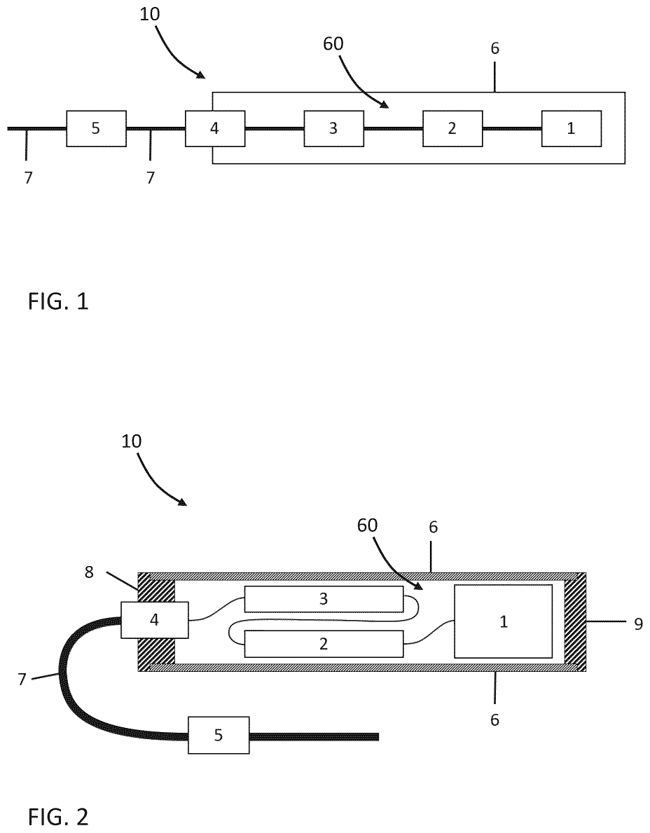

Referring to FIG. 1, a schematic representation is provided of the magnetic detection device 10 for measuring magnetic properties below the surface of the ground according to an embodiment of the invention. Referring also to FIG. 2, a cross-sectional view of the magnetic detection device 10 according to an embodiment is shown. The shown embodiment of the magnetic detection device 10 comprises at least one sensor housing 6, the sensor housing 6 defining a housing space 60. The sensor housing 6 is arranged to prevent the ingress of water into the housing space 60 such that the magnetic detection device 10 can be towed behind a vessel without damaging the internal components in the sensor housing 6.

The shown embodiment of the magnetic detection device 10 comprises at least one optically pumped magnetometer 1 provided in the housing space 60 of the sensor housing 6. The optically pumped magnetometer 1 is an optically pumped vector magnetometer arranged to provide information on a magnetic field in three substantially orthogonal directions. The use of an optically pumped vector magnetometer 1 is advantageous as it is able to provide information on a magnetic field in three substantially orthogonal directions at a single point in time. That is, the optically pumped vector magnetometer 1 provides information about the total magnetic field and on the individual vector components in three orthogonal directions. The magnetometer 1 provides this information at a single location and at a single point in time, to provide an improved information quality and density. Furthermore, the application of an optically pumped magnetometer 1, rather than the traditional total field magnetometers, leads to a significant reduction in weight of the overall system since the optically pumped magnetometer 1 is very light.

The shown magnetic detection device 10 comprises an electronic control unit 2 and a communications board 3. These operate the magnetometer 1 and arrange the data transmission from the magnetometer 1 to e.g., a tow vessel. The electronic control unit 2 is arranged to instruct the optically pumped vector magnetometer 1 and to instruct when the magnetometer 1 takes the measurements.

The electronic control unit 2 is arranged to control the heating of the vapour cell of the optically pumped vector magnetometer 1 and is arranged to monitor characteristics of the optically pumped vector magnetometer 1 through one or more sensors provided therein. For example, the electronic control unit 2 may monitor the temperature of the vapour cell.

The electronic control unit 2 may further control the laser state and frequency of the laser in the optically pumped vector magnetometer 1, as well as detect and control the operational status of the one or more sensors in the optically pumped vector magnetometer 1. Furthermore, the electronic control unit 2 may sample the resulting data stream received from the optically pumped vector magnetometer 1 and may apply appropriate filtering to the incoming sensor data. A user may input the appropriate data filter. Alternatively, or additionally, the appropriate data filter may be determined by the system itself. For example, a noise filter may be applied to the data from the optically pumped vector magnetometer 1.

The communications board 3 then transmits the measurement results and/or measurement confirmation through to a tow vessel. The communications board 3 may also communicate information from a motion sensor to the tow vessel, so that measurement results from the magnetometer 1 can be correlated to positional data of the magnetic detection device 10.

The communications board 3 receives the output of the sensor from the electronic control unit 2 and is arranged to package the data for transmission in an appropriate format. Such format may e.g., be provided through the application of a USB protocol or RS232 protocol for use in a topside recording device such as a computer hard drive. The communications board 3 may also incorporate data from other sensors, such as e.g., the motion sensors, timing systems, altimeter, temperature sensors, or the like, in the data to be transmitted from the communications board 3.

The shown magnetic detection device 10 further comprises a bulkhead connector 4. The bulkhead connector 4 is arranged to provide a leak-proof transmission from the housing space 60 to the outside, allowing for data transmission between the magnetometer 1 and a tow line 7 arranged to transmit data from the magnetometer 1 to e.g., a tow vessel.

The tow line 7 is arranged to transfer a towing force to the sensor housing 6. The tow line 7 may also be a data and/or power cable. If the tow line 7 is also a power cable, a power converter 5 may be provided in the tow line 7. The power converter 5 may also contain a synchronisation pass-through function. The power converter 5 may be arranged to allow for conversion of transmitted power from e.g., a tow vessel to the sensor housing 6. The provision of such a power converter 5 in the tow line 7 rather than in the sensor housing 6 is advantageous since it reduces the need for specially made sensor housing 6 and its contents. Rather, if the magnetic detection device 10 is used in a situation where another power supply is used, only the tow line 7 with the power converter 5 needs to be adjusted, rather than the sensor housing 6 with its internal components. As a result, the use of a power converter 5 in the tow line 7 allows for a generic production of the sensor housing 6 with the magnetometer 1 contained therein, thus reducing production costs.

The magnetic detection device shown in FIG. 2 also comprises a removable endcap 8 and a fixed endcap 9. These are arranged to keep the sensor housing 6 watertight to ensure no water leaks into the housing space 60. The removable endcap 8 and the fixed endcap 9 may be any suitable endcap and have any suitable geometry to attain the required depth rating of the sensor housing 6. It is advantageous to have a removable endcap 8 provided to at least one end of the sensor housing 6 since it provides the possibility of accessing the housing space 60 without having to irreversibly damage the sensor housing 6.

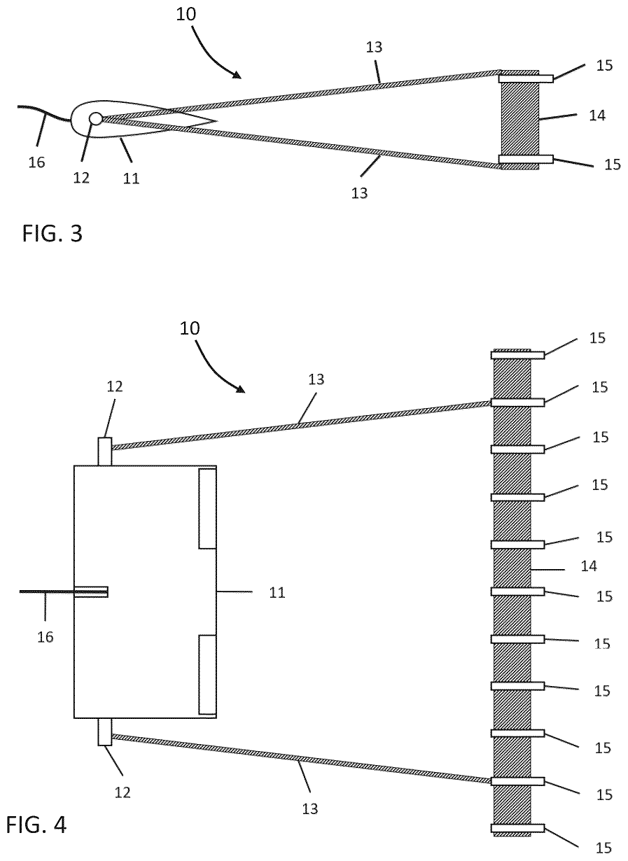

Now referring to FIG. 3, a side view of the magnetic detection device 10 according to an embodiment of the invention is shown. The magnetic detection device 1 of FIG. 3 comprises a frame 14 comprising two deployment frame arms 13. There may be more deployment frame arms 13 than those shown in the FIG. 3 embodiment. Two sensor housings 15 are positioned at a vertical distance from one another and are attached to the frame 14. There may be more sensor housings 15 positioned behind the shown sensor housings. The magnetic detection device further comprises a subsea tow body 11, which is pivotably connected to the deployment frame arms 13 through axis 12. A tow line 16 is attached to the subsea tow body 11 to translate a towing force to the sensor housings 15 through the frame 14.

The subsea tow body 11 may be actively operated to adjust the depth of the magnetic detection device 1 and the magnetometers provided in the sensor housings 15. The subsea tow body 11 may be actuated around axis 12, to adjust the angle of the tow-body with respect to the vessel which tows the magnetic detection device 10 through tow line 16. The adjustment of the subsea tow body 11 alters the angle of attack in relation to the water through which the magnetic detection device 10 is towed.

The tow body 11 advantageously comprises a hydrodynamic surface, which is arranged to provide lift to the magnetic detection device 10. With the actuation of the subsea tow body 11, the depth of the magnetic detection device 10 may thus be adjusted. Alternatively, the subsea tow body 11 is not actuated in an active manner but is passively towed behind the tow vessel through tow line 16. In such an embodiment, the subsea tow body 11 is arranged to stabilise the magnetic detection device 10 within the water as it is towed behind the tow vessel.

Now referring to FIG. 4, a top view of the magnetic detection device 1 according to an embodiment of the invention is shown. A plurality of sensor housings 15 are positioned on a frame 14, which comprises two (or more) deployment frame arms 13. The magnetic detection device further comprises a subsea tow body 11, which is pivotably connected to the deployment frame arms 13 through axis 12. A tow line 16 is attached to the subsea tow body 11 to translate a towing force to the sensor housings 15 through the frame 14.

In an alternative or additional embodiment, the sensor housings 15 may be separately positioned on deployment frame arms without being positioned on the frame 14. In such an embodiment, the deployment frame arms each carry at least one sensor housing 15.

The invention has been described by reference to certain embodiments discussed above. It will be recognized that these embodiments are susceptible to various modifications and alternative forms well known to those of skill in the art.

Further modifications in addition to those described above may be made to the structures and techniques described herein without departing from the spirit and scope of the invention. Accordingly, although specific embodiments have been described, these are examples only and are not limiting upon the scope of the invention.

1. A Magnetic ground detection device for measuring magnetic properties below the surface of the ground, the magnetic detection device comprising:
at least one sensor housing, the sensor housing defining a housing space; and
at least one optically pumped magnetometer provided in the housing space of the sensor housing,
wherein the optically pumped magnetometer is a vector magnetometer arranged to provide information on a magnetic field in three substantially orthogonal directions.

2. The magnetic detection device according to claim 1, further comprising at least one tow line, the tow line being directly or indirectly attached to the sensor housing.

3. The magnetic detection device according to claim 2, wherein the tow line comprises a power transmission cable.

4. The magnetic detection device of claim 1, wherein one sensor housing has a weight of less than about 5 kg.

5. The magnetic detection device of claim 1, wherein the at least one sensor housing defines a substantially cylindrical shape, having a length of less than about 1,5 m.

6. The magnetic detection device of claim 1, further comprising:
a frame, wherein the frame is arranged to support the at least one sensor housing, and wherein the frame is arranged to translate a towing force to the at least one sensor housing such that the at least one sensor housing can be moved through water.

7. The magnetic detection device of claim 1, further comprising:
a subsea tow body, the subsea tow body being directly or indirectly coupled to the sensor housing, wherein the subsea tow body comprises at least one hydrodynamic surface being arranged to determine a depth of the magnetic detection device.

8. The magnetic detection device of claim 6, wherein the magnetic detection device comprises at least 3 sensor housings, the sensor housings being attached to the frame such that they define distances between one another that are substantially equal.

9. The magnetic detection device of claim 1, further comprising a plurality of sensor housings, each having at least one optically pumped vector magnetometer in its housing space, wherein at least two sensor housings are provided such that they define a vertical distance between them.

10. The magnetic detection device of claim 1, wherein the sensor housing has a depth rating of more than about 10 m.

11. The magnetic detection device of claim 1, wherein the sensor housing comprises a bulkhead connector, arranged to transmit a signal from the housing space of the sensor housing to a tow line being connected to the sensor housing, the bulkhead having an inner connector, and an outer connector, wherein the inner connector is connected to the magnetometer, and the outer connector is connected to the tow line.

12. A Method for detecting subsurface bodies comprising the steps of:
providing the magnetic detection device including: at least one sensor housing, the sensor housing defining a housing space; and
at least one optically pumped magnetometer provided in the housing space of the sensor housing,
wherein the optically pumped magnetometer is a vector magnetometer arranged to provide information on a magnetic field in three substantially orthogonal directions.
deploying the magnetic detection device in a body of water;
moving the magnetic detection device through the body of water; and
retrieving measurements results from the at least one optically pumped vector magnetometer.

13. (canceled)

14. The magnetic detection device of claim 1, wherein the device is coupled to an Autonomous vehicle.

15. A non-transitory Computer readable medium having computer readable instruction stored thereon that, when executed by a processor of a magnetic detection device causes the magnetic detection device to measure characteristics of a magnetic field in three orthogonal directions, wherein the magnetic detection device comprising:
at least one sensor housing, the sensor housing defining a housing space; and
at least one optically pumped magnetometer provided in the housing space of the sensor housing,
wherein the optically pumped magnetometer is a vector magnetometer arranged to provide information on a magnetic field in three substantially orthogonal directions.

16. (canceled)
